(19) United States
(12) Patent Application Publication
(10) Pub. No.: US 2003/0064585 A1
(43) Pub. Date: Apr. 3, 2003

(54) Manufacture of semiconductor device with spacing narrower than lithography limit

(76) Inventors: Yider Wu, Cambell, CA (US); Unsoon Kim, Santa Clara, CA (US); Yu Sun, Saratoga, CA (US); Jean Yang, Sunnyvale, CA (US)

Correspondence Address: Andrew Romero, Renner, Otto, Boisselle & Sklar, LLP, 19th Floor, 1621 Euclid Avenue, Cleveland, OH, 44115-2191, US

(21) Appl. No.: 09/966,637

(22) Filed: Sep. 28, 2001

(51) Int. Cl. H01L 21/4763; H01L 21/44; H01L 21/302

(52) U.S. Cl. 438/669; 438/637; 438/708; 438/595

(57) ABSTRACT

A method for transferring a reduced lithographic image size pattern onto a film on a substrate is disclosed. A photosensitive material having an opening of a minimum size achievable by the limits of lithography is transferred onto a mask layer on a substrate having a film thereon. Reduction in the image size is achieved by establishing sidewalls to the interior vertical surfaces of the opening of the mask layer by depositing a conformal layer, followed by anisotropic etching. The dimension of the opening is reduced by the combined thickness of the two opposite sidewalls. An anisotropic etching of the film transfers a pattern of openings of a minimum size smaller than possible by lithography.

### TECHNICAL FIELD

The present invention generally relates to the manufacture of semiconductor devices and, more specifically, relates to the manufacture of semiconductor devices with spacing narrower than obtainable by conventional lithography.

### BACKGROUND ART

In the semiconductor industry, manufacturers scale down the device dimensions to increase the performance as well as reduce the cost of manufacture. The scaling down of devices has led to the development of several new processing techniques. In the manufacture of certain devices, wet etching has been replaced with dry etching (plasma etching, reactive ion etching and ion milling). Low-resistivity suicides and refractory metals are used as replacements for high-resistivity polysilicon interconnections. Multiple-resists have been developed to compensate for wafer surface variations that thwart accurate fine-line lithography.

However, improved lithography processing techniques continue to be the main factor in the ability to scale devices. Improvements have come in, for example, lithographic tools such as 1:1 optical projection systems fitted with deep-ultraviolet source and optics. Further, new photoresist materials have been introduced. Further still, new processes have been developed such as a multilayer resist utilizing a top resist sensitized to X-ray or electron-beam and a bottom straight optical resist layer(s). Despite the enhancements to lithographic tools, materials and processes, there remains a strong need for the further reduction of lithographic image sizes.

One attempted solution disclosed in U.S. Pat. No. 4,707,218 is a process, which uses a mask of photosensitive material having an opening of a minimum size, dictated by the limits of lithography, formed on a substrate. Reduction in the image size is achieved by establishing sidewalls to the interior vertical surfaces of the opening by depositing a conformal layer, followed by anisotropic etching. The dimension of the opening is reduced by the combined thickness of the two opposite insulator sidewalls. However, this process has the drawback wherein the photosensitive material is removed and cannot be used as part of a semiconductor device, also, the photosensitive material etch selectivity may not be good enough for the subsequent processes thereby necessitating the deposition or growth of additional layers and patterning of those additional layers.

Therefore, there exists a strong need in the art for an invention which reduces lithographic image sizes on masks made of materials other than photosensitive material as well as films by extending the lithographic resolution to smaller sizes than capable by conventional lithography alone.

### SUMMARY OF THE INVENTION

According to one aspect of the invention, the invention is a method of patterning a film with an opening of a size smaller than achievable by conventional lithography. The method includes the step of providing a substrate having the film to be patterned interposed between the substrate and a mask layer to be patterned. Next, the mask layer to be patterned is coated with a photosensitive material. This is followed by patterning and etching the photosensitive material to form an opening therein, the opening having substantially vertical walls and a minimum size dictated by a resolution limit of conventional lithography. Then, the patterned image of the photosensitive material is transferred to the mask layer by anisotropically etching the mask to form an opening therein, the opening having substantially vertical walls and a minimum size dictated by a resolution limit of conventional lithography. After removal of the photosensitive material, sidewall spacers are formed on the vertical walls of the mask layer whereby the size of the opening is reduced.

Finally, the film is etched to form an opening therein, the opening having substantially vertical walls and an opening size which is smaller than achievable by a resolution limit of conventional lithography. The mask layer is removed by an etch process thereafter.

According to another aspect of the invention, the invention is a method for forming a patterned film on a substrate surface for integrated circuit manufacture. The method includes the step providing a substrate covered with a film of a first material. A mask layer of a second material is formed on the film. Next, the mask layer is coated with a photosensitive layer having an opening of a minimum size dictated by the resolution limit of conventional lithography, the opening having substantially vertical surfaces. The mask layer is anisotropically etched to transfer thereto an image of the photosensitive layer having an opening of the minimum size dictated by the resolution limit of conventional lithography. An opening in the mask layer has substantially vertical surfaces. Thus, the second material layer is transformed into a mask for the film. Next, a conformal layer is deposited on the second material including the vertical surfaces and on the film exposed by the opening. Then, an anisotropical etching removes the conformal layer from everywhere except the walls of the opening, thereby reducing the size of the opening by approximately twice the thickness of the conformal layer. Further, an anisotropical etch of the film of the first material transfers thereto an image of the mask layer having an opening of reduced size.

### BRIEF DESCRIPTION OF DRAWINGS

These and further features of the present invention will be apparent with reference to the following description and drawings, wherein:

FIG. 1 is a cross-section of a patterned film on a substrate having a pattern of opening(s) smaller than achievable by conventional lithography according to an embodiment of the present invention;

FIGS. 2-6 are sequential cross-sections of a method of manufacturing the patterned film according to the present invention at intermediate stages of manufacture;

FIG. 7 is a flow diagram of a method of manufacturing the patterned film according to the present invention.

### DISCLOSURE OF INVENTION

To illustrate the present invention in a clear and concise manner, the drawings may not necessarily be to scale and certain features may be shown in a partial schematic format.

The present invention is a film layer, semiconductor device or the like comprising a line and space pattern having a spacing narrower than the smallest spacing achievable by conventional lithography processes alone. The film layer or semiconductor device is formed on a substrate or may be formed on another layer of film. In one embodiment, the semiconductor device comprises a film layer formed on the substrate patterned with an opening or spacing having a dimension smaller than that achievable by conventional lithography processes alone.

The invention provides a method of reducing the size of a lithographic image in a photoresistive layer used to obtain the image by establishing a sidewall on the interior of the opening in a mask layer formed from the transfer of the lithographic image. Starting with a substrate (e.g., semiconductor, insulator or metal), a film to be patterned is formed on the substrate. Next, a mask layer of, for example, an insulator material, such as silicon dioxide, is formed on the film to be patterned. Then, a layer of photosensitive material is applied. The layer of photosensitive material is patterned by lithographic means to have openings of a minimum spacing dictated by the limits of conventional lithography.

Next, the lithographic image is transferred to the mask layer producing openings in the mask layer of a minimum spacing dictated by the limits of conventional lithography. Thereafter, to further reduce the size of the openings, a conformal layer material is applied to the mask layer and the film layer portions exposed by the openings in the mask layer. The thickness of the conformal layer material is determined by the desired reduction in the size of the openings of a minimum size dictated by the limits of conventional lithography. For example, for an elongated opening, the reduction in the width of the opening is approximately twice the thickness of the conformal layer. An example of the conformal layer material is SiₓO_{y} formed by plasma-deposited hexamethyidisilazane (HMDS). By directional reactive ion etching (RIE), the conformal layer is removed from all the horizontal surfaces leaving sidewalls of the conformal layer material on the non-horizontal surfaces corresponding to the openings in the mask layer. The film layer exposed by the openings in the mask layer may also be removed by RIE.

The mask layer in combination with the sidewalls of the conformal layer material constitutes a new mask (stencil) having openings smaller than obtainable by lithography alone. This mask can be used for a variety of purposes including ion implantation to implant the film layer. If the substrate is exposed by the reduced-dimensioned openings in the film layer, it may also be implanted. Further, the new mask may be used as a RIE mask to etch narrow trenches in the film layer, substrate or both. Further still, the new mask may be used as an oxidation mask to form recessed oxide isolation in the exposed regions of the film layer or semiconductor substrate. Additionally, the new mask may be used as a contact mask to establish narrow dimensioned contacts on the film layer or substrate, etc. Following such use, the new mask may be removed from the film by subjecting the mask layer and spacers to a wet or dry etchant.

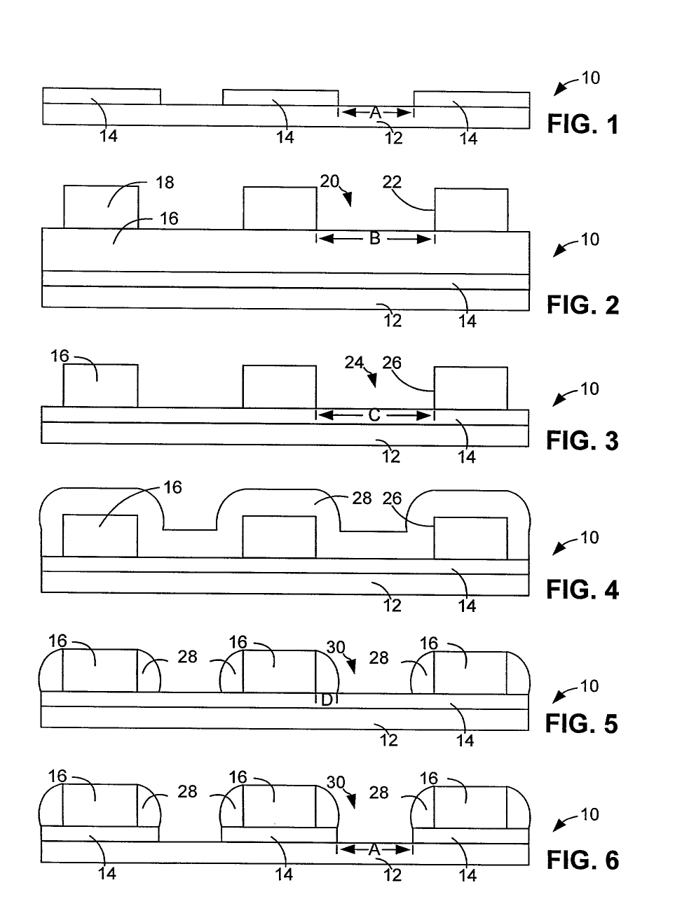

Referring initially to FIG. 1, an embodiment of a semiconductor device 10 will now be described in more detail. The semiconductor device 10 is formed using a semiconductor substrate 12, and a film layer 14 formed on the semiconductor substrate 12. The film layer 14 is patterned with openings or spacings of a dimension A, which may be smaller than obtainable by conventional lithography alone. An exemplary film layer 14 may have a thickness of between 50 Å and 10000 Å. Suitable materials such as polysilicon, amorphous silicon, silicon/germanium, oxides, nitrides or the like, may be used as the film layer 14. The film layer 14 is illustrated in FIG. 1 as a single film layer, however the film layer could be a multi-layer film.

Although the illustrated device is a semiconductor device with a film patterned on a substrate, other devices can also be improved using the narrower spacing characteristics of the method of reducing the spacing narrower than the lithography limit described herein.

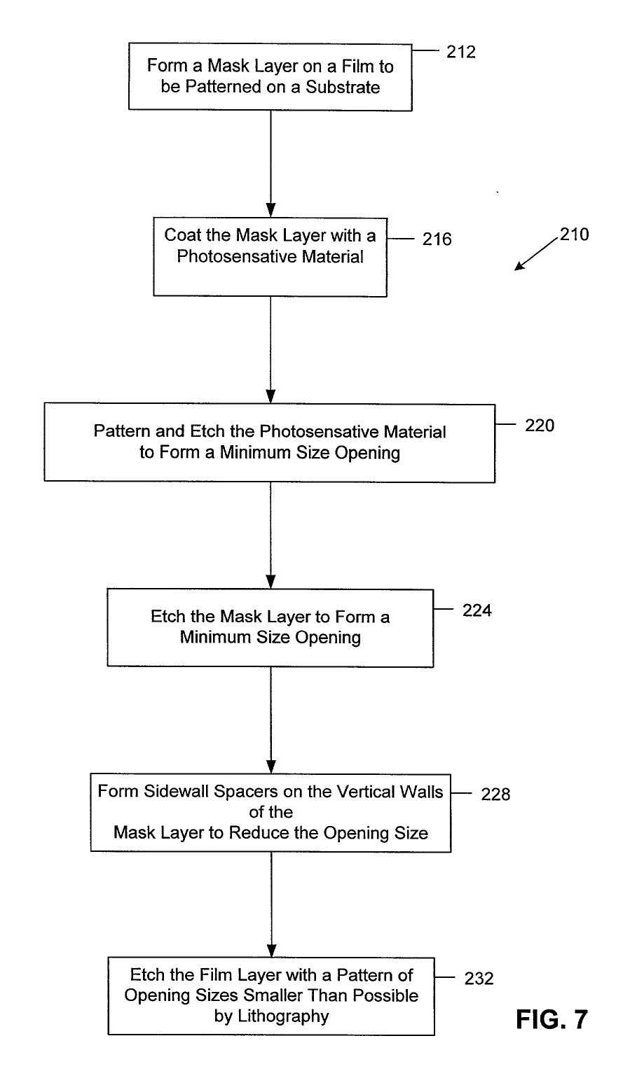

The steps of a method 210 for fabricating a device 10 are outlined in the flow chart shown in FIG. 7. FIGS. 2-6 illustrate various steps of the method 210. It will be appreciated that the method 210 and the semiconductor device 10 described below are merely exemplary, and that suitable embodiments of the many above-described variations in materials, thicknesses, and/or structures may alternatively be used in the method 210 and/or the semiconductor device 10.

In step 212, as represented in FIG. 2, a structure representing an intermediate step of the manufacturing process is shown. The method is initiated with a substrate 12. The substrate 12 may be any material upon which a film layer 14 to be patterned may be formed. For example, the substrate 12 may be a semiconductor material, glass, insulator, primary photosensitive material, metal or a combination thereof. The film layer 14 may be of any material on which a mask layer 16 may be formed. The mask layer 16 may be of any known mask material on which a photoactive imaging layer 18 can be coated and patterned by conventional lithographic techniques.

The film layer 14 of nitride, for example, is applied to the substrate 12 using known techniques such as spin-coating or any PVD or CVD process. The film layer 14 may be, for example, 50 Å-10,000 Å thick. After forming the film layer 14, a mask layer 16 is formed on the film layer 14 again using conventional techniques. The mask layer 16 may be 50 Å-10,000 Å thick, for example. The mask layer 16 material may be silicon dioxide, SiₓO_{y}, silicon nitride, silicon oxynitride, aluminum oxide (Al₂O₃), hafnium oxide (HfO₂), zirconium oxide (ZrO₂), tantalum oxide (Ta₂O₅), polysilicon, amorphous silicon, or the like.

Next in step 216, an imaging layer 18 of a photosensitive material is applied, for example, by spin-coating. The imaging layer 18 may have a thickness in the range of about 300 Å-5000 Å, for example. An exemplary material for imaging layer 18 is AZ 1350J photoresist. Then, in step 220, the imaging layer 18 is patterned by pattern-exposing using a conventional lithographic tool, developed, rinsed and dried. Then, an anisotropic etching is conducted to form openings 20 in the imaging layer 18 according to the pattern. For simplicity of illustration, in FIG. 2 only two openings 20 having a lateral dimension B are shown in the imaging layer 18. The openings 20 have substantially vertical surfaces 22. The dimension B represents, for example, the smallest image size that is obtainable by the conventional lithography utilized in step 220. For example, the width B may be the smallest dimension that is achievable by pushing known lithography (which includes x-ray, electron-beam, etc.) to its highest resolution limit. Next, the imaging layer 18 is subjected to a hardening process step to thermally stabilize the imaging layer 18. Deep ultraviolet exposure or heat treatment at a temperature of about 200° C.-250° C. for about 1-2 minutes may be used for hardening. Another method of hardening the imaging layer 18 is by subjecting it to a halogen gas plasma. This hardening step is needed for conventional photoresists, lest the photosensitive material constituting imaging layer 18 may melt and flow or otherwise get degraded during the subsequent processes.

Next in step 224 as illustrated in FIG. 3, an anisotropic etching is conducted to transfer the lithographic image from the imaging layer 18 to the mask layer 16. The etchant removes the exposed mask layer 16 in the openings 20 leaving openings 24 having a lateral dimension C in the mask layer 16. The openings 24 have substantially vertical surfaces 26. The dimension C is approximately equal to dimension B. A subsequent anisotropic etching removes the remaining imaging layer 18. Thus, the smallest image size that is obtainable by the conventional lithography in step 220 is transferred from the imaging layer 18 to the mask layer 16.

In the next step 228, as illustrated in FIGS. 4-5, sidewalls are formed on the vertical surfaces 26 to reduce the lateral dimension C of the opening 24 beyond that achievable by conventional lithography alone. According to one method, a conformal layer 28 is formed over the patterned mask layer 16 and the portion of the film layer 14 exposed by the openings 24 therein as represented in FIG. 4. In general, the conformal layer 28 may be any material which can be deposited on the patterned mask layer 16. Examples of conformal layer 28 material include silicon dioxide, SiₓO_{y}, silicon nitride, silicon oxynitride, aluminum oxide (Al₂O₃), hafnium oxide (HfO₂), zirconium oxide (ZrO₂), tantalum oxide (Ta₂O₅), polysilicon, amorphous silicon or the like, or a combination thereof. In a particular embodiment, the conformal layer 28 may be of the same material as the mask layer 16. An example material for conformal layer 28 is SiₓO_{y}, obtained by hexamethyidisilazane (HMDS) plasma deposition.

Typically, the conformal layer 28 is formed by mounting the substrate with the structure of FIG. 3 in a plasma deposition system. Then, liquid HMDS is introduced into the process chamber and the necessary electric field is generated therein which transforms the liquid HMDS into a HMDS plasma. The HMDS plasma will deposit on the structure of FIG. 3 obtaining a uniform conformal layer 28 of plasma-deposited HMDS having the composition SiₓO_{y}.

The thickness D of conformal layer 28 is determined by the desired reduction in the lithographic image size in the mask layer 16. Typically, for very large scale integrated circuit fabrication, the thickness of conformal layer 28 is in the range of about 50 Å-5000 Å. The lower limit for the thickness of conformal layer 28 is dictated by the requirements of good step coverage associated with the substantially vertical wall 26 profile in mask layer 16 and viability of the conformal layer 28 as a thin film. The upper limit for the thickness of conformal layer 28 is determined by the desired percentage reduction in the size of the opening 24 in the mask layer 16. The percentage reduction in the opening size is governed by the factor 2D/A. In other words, if the size of the opening is 150 Å, in order to achieve a 66.6% reduction in the size of the opening 24 (or an actual reduction of the opening size to 50 Å), a 50 Å thick HMDS or other spacer material conformal layer 28 is deposited. Next, the conformal layer 28 is anisotropically etched to remove it from all the substantially horizontal surfaces leaving it only on the substantially vertical surfaces 26 of the mask layer 16.

The resulting structure will be as shown in FIG. 5 where the unetched portions of conformal layer 28 now serve as sidewalls on the vertical surfaces 26 of the mask layer 16. Due to the establishment of the sidewalls from the conformal layer 28 on the interior of the vertical surfaces 26, the opening 24 is reduced in size to a new opening 30 of a dimension designated as A in FIG. 6. The relationship between the parameters A, C and D is given by: A=C−2D.

Following the establishment of the sidewalls 28 on the vertical surfaces 26 of the mask layer 16, the portion of the film layer 14 exposed by the reduced-size opening 30 is removed by RIE. The RIE etchant used may be, for example, the same etchant species which facilitated removal of conformal layer 28 from the horizontal surfaces of the mask layer 16. Alternatively, the etchant used may be O₂ plasma.

The mask layer 16 in combination with the sidewalls 28 fabricated in this manner constitutes a new mask (or stencil) having openings of a substantially reduced dimension than obtainable by conventional lithography alone. The new mask may serve a variety of purposes. For example, it may be used as an ion implantation mask to implant an extremely narrow/small region of the substrate 10. Another application of the new mask is as an etch mask to etch extremely narrow deep/shallow trenches in the substrate 10. Yet another application is to grow a recessed isolation oxide free of bird's beak and bird's head of a width essentially equal to the dimension A by subjecting the substrate and the overlying stencil structure to a low temperature oxidation. A further use of the new mask is as a contact (liftoff) mask for establishing highly localized electrical contacts to the substrate. Another use of the mask is to form narrow conductor or insulator lines of width A on the substrate.

Once the intended use of the new mask is complete, it may be removed from the substrate 10 by subjecting the mask layer 16 and sidewall spacers 28 to a suitable etchant for example, a hot oxidizing acid such as nitric acid, sulphuric acid, or hot phenol. Alternatively, the mask layer 16 and the sidewalls 28 may be removed concurrently by oxygen plasma. Any sidewall material 28 that remains may be removed by mechanical means, a plasma etch or washed off in a liquid base.

An example of a device, which may take advantage of the reduction of the spacing narrower than the conventional lithographic limit, is a FLASH memory cell. In particular, the formation of a floating gate for such a device. Such a FLASH memory cell would be capable of operating at significantly higher speeds than traditional FLASH memory cell devices formed on conventional structures. Additionally, the scaling of the FLASH memory cell would allow a higher yield per wafer.

It will further be appreciated that the semiconductor device 10 may alternatively have other shapes than the shape shown in FIG. 1. Thus, there has been disclosed a method of reducing lithographic image size that fully satisfies the objects and advantages set forth above. This method permits reduction in lithographic image size over and beyond that possible by improved lithographic resolution brought about by lithography tool enhancements.

Although particular embodiments of the invention have been described in detail, it is understood that the invention is not limited correspondingly in scope, but includes all changes, modifications and equivalents coming within the spirit and terms of the claims appended hereto.

What is claimed is:

1. A method for patterning a film with an opening of a size smaller than achievable by lithography, comprising:
providing a substrate having the film to be patterned interposed between the substrate and a mask layer to be patterned;
coating the mask layer to be patterned with a photosensitive material;
patterning and etching the photosensitive material to form an opening therein, the opening having substantially vertical walls and a minimum size dictated by a resolution limit of conventional lithography;
transferring to the mask layer the patterned image of the photosensitive material by anisotropically etching the mask layer to form an opening therein, the opening having substantially vertical walls and a minimum size dictated by a resolution limit of conventional lithography;
forming sidewall spacers on the vertical walls of the mask layer whereby the size of the opening is reduced; and
etching the film to form an opening therein, the opening having substantially vertical walls and an opening size which is smaller than achievable by a resolution limit of conventional lithography.

2. The method according to claim 1, wherein the mask layer material is silicon dioxide, SiₓO_{y}, silicon nitride, silicon oxynitride, aluminum oxide (Al₂O₃), hafnium oxide (HfO₂), zirconium oxide (ZrO₂), tantalum oxide (Ta₂O₅), polysilicon, amorphous silicon or the like.

3. The method according to claim 1, wherein the film to be patterned material is polysilicon, amorphous silicon, Si/Ge, oxide, nitride or the like.

4. The method according to claim 1, wherein the photosensitive material is photoresist.

5. The method according to claim 1, further comprising hardening the photosensitive material prior to etching the mask layer.

6. A method for reducing the size of a lithographic image in a film comprising:
forming on a substrate a film to be patterned;
forming on the film a mask material having at least one opening of minimum size C determined by the resolution limit of lithographic exposure tooling, the opening having substantially vertical interior walls; and establishing sidewalls of a material of a thickness D on the walls, whereby the new size A of the opening is at least approximately C−2D.

7. The method as recited in claim 6 wherein the sidewall material has a lower etch rate than that of the film enabling the mask material in combination with the sidewalls to function as an etch mask for etching the film.

8. The method as recited in claim 6 wherein the step of establishing sidewalls comprises:
forming a conformal layer of the sidewall material; and
anisotropically etching to remove the sidewall material from everywhere except the walls of the opening.

9. Method for forming a patterned film on a substrate surface for integrated circuit manufacture comprising:
providing a substrate covered with a film of a first material;
forming a mask layer of a second material on the film;
coating the mask layer with a photosensitive layer having an opening of a minimum size dictated by the resolution limit of conventional lithography, the opening having substantially vertical surfaces;
anisotropically etching the mask layer to transfer thereto an image of the photosensitive layer having the opening of the minimum size dictated by the resolution limit of conventional lithography, an opening in the mask layer having substantially vertical surfaces and transforming the second material layer into a mask for the film;
depositing a conformal layer on the second material including the vertical surfaces and on the film exposed by the opening;
anisotropically etching to remove the conformal layer from everywhere except the walls of the opening, thereby reducing the size of the opening by approximately twice the thickness of the conformal layer; and
anisotropically etching the film of the first material to transfer thereto an image of the mask layer having the opening of reduced size.

10. The method as recited in claim 9 further comprising removing the photosensitive layer with the opening therein following the etching of the second material.
